(19) United States
(12) Patent Application Publication
(10) Pub. No.: US 2015/0364348 A1
(43) Pub. Date: Dec. 17, 2015

(54) GAS PHASE ETCHING APPARATUS

(71) Applicant: KOOKJE ELECTRIC KOREA CO., LTD., Cheonan-si Chungcheongnam-do (KR)

(72) Inventors: Young-Woo PARK, Cheonan-si (KR); Yong Sung PARK, Cheonan-si (KR); Dong Yeul KIM, Cheonan-si (KR)

(21) Appl. No.: 14/764,460

(22) PCT Filed: Feb. 11, 2014
(86) PCT No.: PCT/KR2014/001117

§ 371 Date: Jul. 29, 2015

(30) Foreign Application Priority Data
Feb. 20, 2013 (KR) 10-2013-0018040

(51) Int. Cl. H01L 21/67; H01L 21/677

(52) U.S. Cl. CPC H01L 21/67069; H01L 21/67742; H01L 21/67751

(57) ABSTRACT

Provided is a gas phase etching apparatus. The gas phase etching apparatus includes a process chamber having an inner space that is defined by a chamber body having an opened upper portion and an upper dome having an opened lower portion and detachably coupled to an upper portion of the chamber body, a substrate susceptor disposed in the inner space to ascend and descend by a driving unit, and a ring plate disposed on the substrate susceptor to cover a space between the substrate susceptor and an outer wall of the process chamber so that the inner space is partitioned into a process region defined above the substrate susceptor and an exhaust region defined below the substrate susceptor. The process region partitioned by the ring plate is surrounded by the upper dome, and the exhaust region is surrounded by the chamber body.

### TECHNICAL FIELD

The present invention disclosed herein relates to a gas phase etching apparatus in which a process of etching a film is performed in a chamber by using a gas.

### BACKGROUND ART

Generally, in processes of manufacturing semiconductors, a series of treating processes may be repeatedly performed on a silicon wafer being used as a substrate, and thus various integrated circuit devices may be formed on the substrate. For example, a process of removing materials from a certain area, i.e., an etching process is essential to form patterns in the processes of manufacturing semiconductors. For example, there are a wet etching process for removing materials by using a suitable etching solution and a dry etching process for removing materials in a vapor condition.

The dry etching may be largely classified into ion etching and reaction etching. The ion etching is a method using a phenomenon in which atoms are pulled out from a surface of a material when high-energy ions collide with the surface of the material, i.e., a sputtering phenomenon. In the ion etching method, chemical reaction may be minimized, and the material is etched by physical reaction. The ion etching is called ion beam etching, ion beam milling, or sputter etching.

The reaction etching includes chemical reaction etching using only chemical reaction of a reactive gas and plasma etching in which a reactive gas is plasmarized to perform chemical reaction and sputtering at the same time, thereby increasing an anisotropic etching property and an etching rate.

As above-described dry etching processes are mostly performed in a vacuum chamber. For example, when a highly corrosive gas such as a chlorine (Cl2) gas is used, the corrosive gas reacts with the chamber and other attached members such as gas lines due to the high reactivity of the chlorine gas to cause corrosion and contamination phenomena which cause contamination and particle sources.

Therefore, when the dry etching equipment perform the general dry etching processes, an inner wall of the chamber may corrode to serve as a cause of the contamination of a wafer and as particle sources. As a result, a loss such as equipment stop due to preventive maintenance (PM) of the equipment may increase to reduce productivity.

### DISCLOSURE OF THE INVENTION

### Technical Problem

The present invention provides a gas phase etching apparatus that is resistant to a reactive gas.

The present invention also provides a gas phase etching apparatus which is capable of preventing a process chamber from corroding.

The feature of the present invention is not limited to the aforesaid, but other features not described herein will be clearly understood by those skilled in the art from descriptions below.

### Technical Solution

Embodiments of the present invention provide gas phase etching apparatuses including: a process chamber having an inner space that is defined by a chamber body having an opened upper portion and an upper dome having an opened lower portion and detachably coupled to an upper portion of the chamber body; a substrate susceptor disposed in the inner space to ascend and descend by a driving unit; and a ring plate disposed on the substrate susceptor to cover a space between the substrate susceptor and an outer wall of the process chamber so that the inner space is partitioned into a process region defined above the substrate susceptor and an exhaust region defined below the substrate susceptor; wherein the process region partitioned by the ring plate is surrounded by the upper dome, and the exhaust region is surrounded by the chamber body.

In some embodiments, the gas phase etching apparatuses may further include a gas injection unit disposed on the upper dome to face the substrate susceptor, the gas injection unit receiving a reactive gas from a gas supply device to supply the reactive gas to the process region.

In other embodiments, the gas injection unit may include: a circular gas introduction plate formed of a quartz material, the circular gas introduction plate being connected to a gas supply tube at an upper central portion thereof to diffuse the reactive gas downward; and a shower plate formed of the quarts material and coupled to a lower portion of the circular gas introduction plate, wherein a plurality of injection holes may vertically pass through the shower plate to inject the reactive gas supplied through the circular gas introduction plate downward.

In still other embodiments, the ring plate may include a plurality of exhaust holes.

In even other embodiments, the upper dome may be formed of the quartz material.

In yet other embodiments, each of the upper dome, the substrate susceptor, and the ring plate which surround the process region may be formed of the quartz material.

In further embodiments, the process chamber may further include a substrate entrance disposed in one side of the chamber body to provide a passage for loading/unloading the substrate into/from the inner space of the process chamber, and the ring plate may further include a cover vertically extending from an edge thereof and interlocked with the ascending/descending operations of the substrate susceptor to open or close the passage of the substrate entrance to allow the passage of the substrate entrance to be partitioned as an independent space with respect to the inner space of the process chamber.

In still further embodiments, the gas phase etching apparatuses may further include a purge supply unit for supplying an inert gas into the passage of the substrate entrance, wherein the substrate entrance may include a gas supply hole through which the inert gas supplied through the purge supply unit is supplied into the passage.

In even further embodiments, the chamber body may be formed of a hastelloy material and has a surface treated through electrolytic polishing or complex electrolytic polishing.

### Advantageous Effects

According to the embodiments of the present invention, the reactive gas supplied into the process region may not contact other metals except for the quartz material, thereby preventing the process chamber from being contaminated due to the reaction between the reactive gas and the metals.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of a substrate treating apparatus according to an embodiment of the present invention;

FIG. 2 is a cross-sectional view of a state where a substrate susceptor descends;

FIG. 3 is a plan cross-sectional view of the substrate treating apparatus illustrated in FIG. 1;

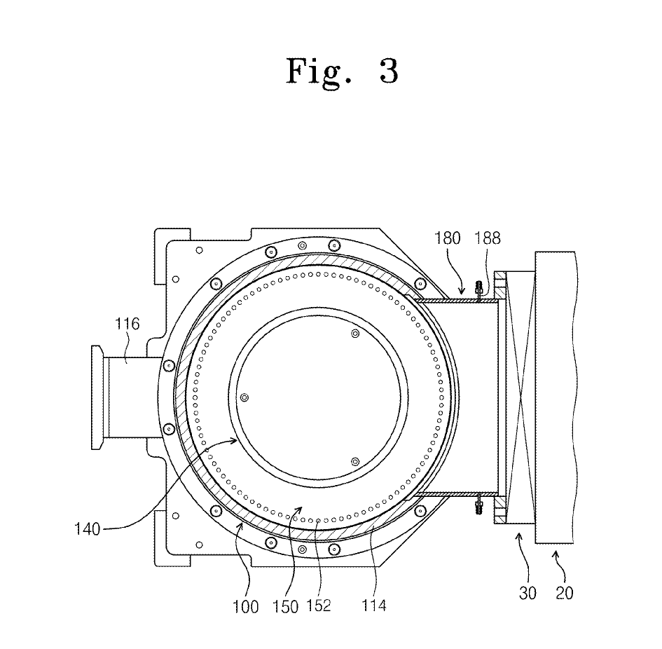

FIG. 4 is a view of a substrate entrance closed by a cover; and

FIG. 5 is a view of the substrate entrance opened by the cover.

### MODE FOR CARRYING OUT THE INVENTION

Hereinafter, a gas phase etching apparatus according to exemplary embodiments of the present invention will be described in detail with reference to the accompanying drawings.

In description of the present invention, detailed descriptions related to well-known functions or configurations will be ruled out in order not to unnecessarily obscure subject matters of the present invention.

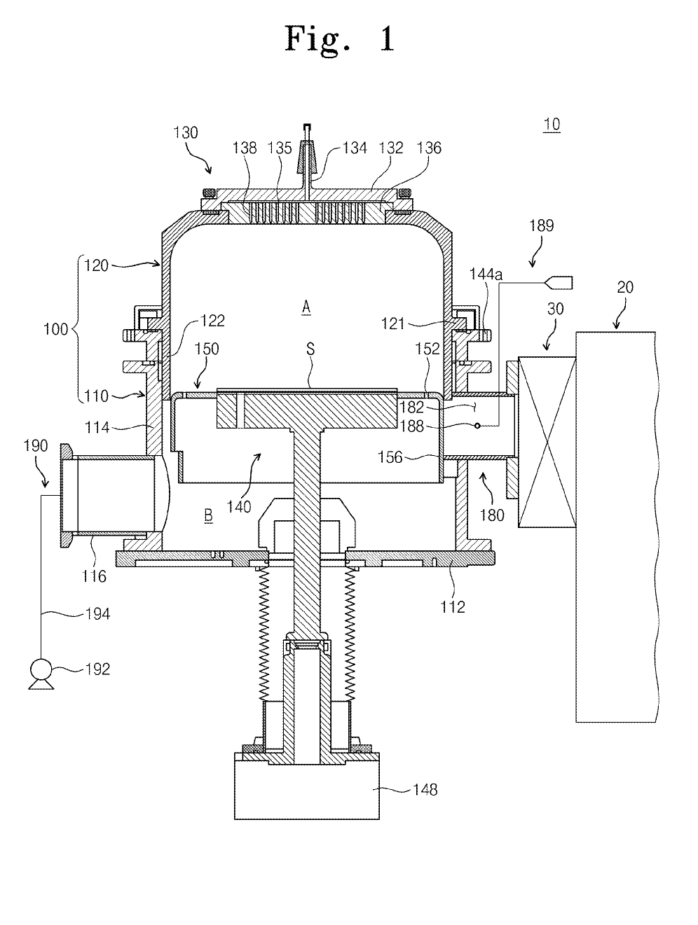

FIG. 1 is a cross-sectional view of a substrate treating apparatus according to an embodiment of the present invention.

In the current embodiment, an apparatus for performing a gas phase etching (GPE) process to etch a surface of a substrate by using an etching gas will be described as an example. However, technical features of the present invention are not limited thereto. For example, the technical features of the present invention may be applied to apparatuses in which only a portion of poly-silicon by using only a reactive gas and heat energy without using plasma to generate the other film thereon.

A substrate to be etched in an etching process may include any substrates such as a glass substrate for a liquid crystal display (LCD) panel, a substrate for a solar cell device, an LED wafer, a semiconductor wafer, an Amoled substrate, and the like.

Referring to FIG. 1, a gas phase etching apparatus 10 according to the present invention includes a process chamber 100, a gas injection unit 130, a substrate susceptor 140, a ring plate 150, and a substrate entrance 180.

The process chamber 100 provides an inner space that is sealed to perform an etching process on a substrate S. The process chamber 100 includes a chamber body 110 having an opened upper portion and an upper dome 120 detachably coupled to the chamber body 110.

The chamber body 110 has the opened upper portion and includes a chamber base 112 that is substantially parallel to the ground and a sidewall 114 substantially vertical to the chamber base 112. The sidewall 114 includes a first flange 114a coupled to the upper dome 120 on an upper end thereof. A vacuum suction port 116 connected to a vacuum pump is disposed on the sidewall 114 of the chamber body 110.

The upper dome 120 may be coupled to an upper portion of the chamber body 110 with a sealing member therebetween to form the sealed inner space together with the chamber body 110. Thus, the upper dome 120 may have a dome shape having an opened lower portion. The upper dome 120 includes a second flange 121 coupled to the first flange 114a disposed on the sidewall 114 of the chamber body 110 and an extending portion 122 extending downward from a position on which the second flange 121 is disposed. The extending portion 122 is disposed inside the side-wall 114 of the chamber body 110 to partially overlap the chamber body 110.

The upper dome 120 may be formed of a quartz material having strong corrosion-resistance in consideration of the etching process in which a reactive gas containing chlorine (Cl) or fluorine (F) is injected. Also, since the chamber body 110 should have an exhaust port 116 and the substrate entrance 180, and the like therein, a quartz material is not used to form the chamber body 110 having low processability. Therefore, the chamber body 110 may be formed of one of nickel hastelloy, ceramic, tungsten, tungsten alloy, aluminum, and aluminum alloy that have strong chemical resistance, excellent processability, and superior weldability, and a surface of the chamber body 110 may be treated through electrolytic polishing or complex electrolytic polishing.

The gas injection unit 130 is disposed on a top surface of the upper dome 120 facing the substrate susceptor 140 to perform the etching process. The gas injection unit 130 is configured to receive an etching gas from a gas supplying device (not shown) to supply the etching gas into a processing space. Here, the gas injection unit 130 may vary in configuration according to a process and a gas supplying method.

In more detail, the gas injection unit 130 includes a circular gas introduction plate 132 and a shower plate 136, and a diffusion space 135 is defined between the circular gas introduction plate 132 and the shower plate 136.

The circular gas introduction plate 132 is formed of a quartz material. The circular gas introduction plate 132 includes a connection port 134 connected to the gas supplying tube (not shown) at an upper central portion thereof. A reactive gas supplied through the connection port 132 is diffused in a lower side (a diffusion space 135) of the circular gas introduction plate 132 and then is supplied to the shower plate 136. An edge of the circular gas introduction plate 132 may be fixed to the upper dome 120 by a plurality of coupling members such as bolts.

The shower plate 136 is formed of the same quartz material as that of the circular gas introduction plate 132. The shower plate 136 is coupled to the lower portion of the circular gas introduction plate 132, and a plurality of injection holes 138 vertically pass through the shower plate 136 to inject the reactive gas supplied through the circular gas introduction plate 132 downward. The injection holes 138 are connected to the diffusion space 135. For example, the injection holes 138 may be spaced a predetermined distance from each other along a concentric circumference to uniformly inject the gas. The reactive gas passes through the circular gas introduction plate 132 and diffused into the diffusion space 135 to flow onto the substrate S disposed on the substrate susceptor 140 through the injection holes 138 defined in the shower plate 136.

Various gases may be selectively used as the reactive gas used for the etching process according to a material of an object to be etched. Also, the reactive gas may not be provided as a single gas, but be provided as a mixture of various gases. For example, the reactive gas may include chlorine or fluorine. Another example of the reactive gas may include a portion of or the entire NF₃, C₂F₆, CF₄, CHF₃, SF₆, Cl₂, BCl₃, and C₂HF₅. Also, the reactive gas may further include a portion of or the entire an inert gas, H₂, and O₂ in addition to the above-described gases.

The substrate susceptor 140 is formed of a quartz material and disposed in an inner space of the process chamber 100. The substrate S loaded through the opened substrate entrance 180 by a robot is placed on the substrate susceptor 140.

The substrate susceptor 140 is configured to support the substrate S so that the etching process is smoothly performed. The substrate susceptor 140 may have various configurations according to design and process conditions. For example, the substrate susceptor 140 may include an electrostatic chuck that is configured to fix the substrate S. Also, the substrate susceptor 140 may include a heater for increasing a temperature of the substrate S during the etching process.

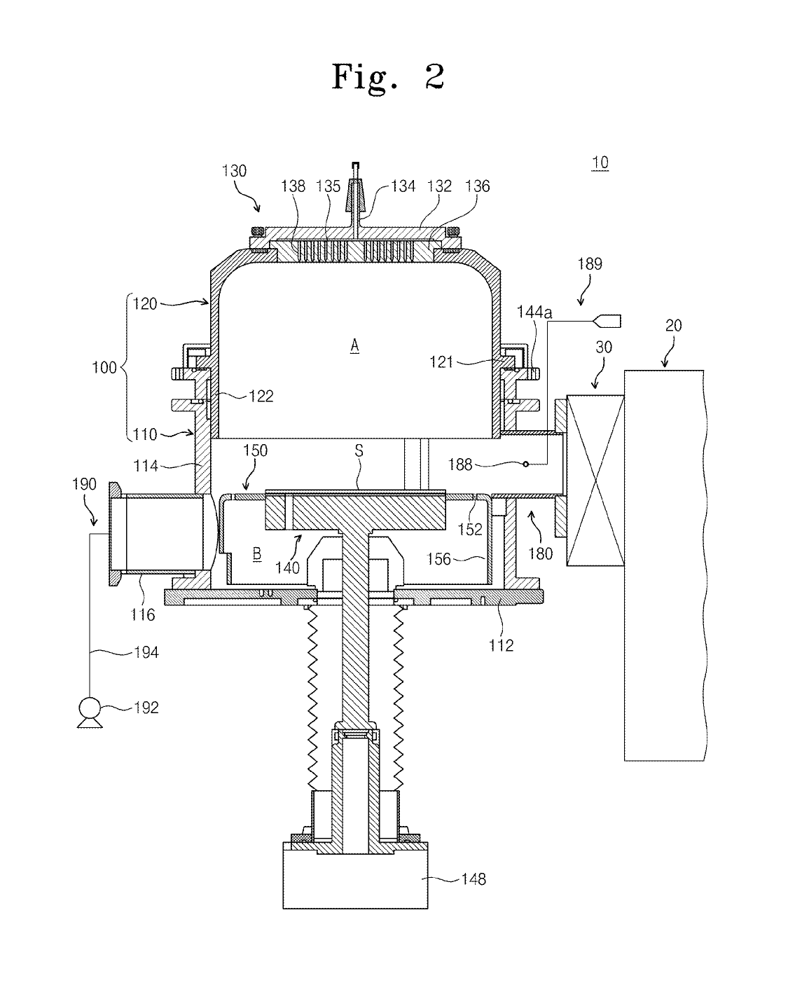

The substrate susceptor 140 ascends or descends by a susceptor driving unit 148. The substrate treating process may be performed in the state where the substrate susceptor 140 ascends as shown in FIG. 1, and the loading or unloading of the substrate S may be performed in the state where the substrate susceptor 140 descends as shown in FIG. 2.

The ring plate 150 is disposed on the substrate susceptor 140. The ring plate 150 is formed of a quartz material and is provided in a shape that covers a space between the substrate susceptor 140 and an outer wall of the process chamber 100. The ring plate 150 may have a top surface that is flush with that of the substrate susceptor 140. When the substrate susceptor 140 ascends, the ring plate 150 may be disposed inside the extending portion 122 of the upper dome, and when the substrate susceptor 140 descends, the ring plate 150 may be disposed inside the chamber body 110.

The inner space of the process chamber 100 is partitioned into a process region A defined above the substrate susceptor 140 and an exhaust region B defined below the substrate susceptor 140 by the substrate susceptor 140 and the ring plate 150. The ring plate 150 may include a plurality of exhaust holes 152 so that a gas flows from the process region A into the exhaust region B.

As described above, the process region A partitioned by the ring plate 150 is surrounded by the upper dome 120 and the gas injection unit 130, and the exhaust region B is surrounded by the chamber body 110. In more detail, the process region A is surrounded by the gas injection unit 130, the upper dome 120, the substrate susceptor 140, and the ring plate 150, each of which are formed of the quartz material to prevent the reactive gas from contacting other metals except for the quartz material while the reactive gas is supplied into the process region A to react with the substrate. Therefore, it may prevent the chamber and the substrate from being contaminated due to the reaction between the reactive gas and the metals.

The inside of the process chamber 100 may become to a vacuum state by a vacuum exhaust unit 190. Also, vacuum exhaust unit 190 may discharge reaction by-products generated during the etching process. The vacuum exhaust unit 190 may include a vacuum pump 192 and a vacuum line 194 connected to a vacuum suction port 116 disposed on the sidewall 114 of the chamber body. Various kinds of valves (not shown) are disposed in the vacuum line 194 connecting the process chamber 100 to the vacuum pump 192 to open or close the vacuum line 194 and adjust an opening/closing degree, thereby adjusting a vacuum degree.

The substrate entrance 180 is disposed in the side-wall 114 of the chamber body 110 facing the vacuum suction port 116. The substrate entrance 180 includes a passage 182 for loading the substrate into and unloading the substrate from the inner space of the process chamber 100. The process chamber 100 is connected to a loadlock chamber 20 through the substrate entrance 180, and a gate valve 30 is disposed between the substrate entrance 180 and the loadlock chamber 20. Also, a gas supply hole 188 is defined in the passage of the substrate entrance 180.

An inert gas is provided to the passage 182 of the substrate entrance 180 through the gas supply hole 188. The inert gas is supplied through a purge supply unit 189. The substrate entrance 180 has one end communicating with the inner space of the process chamber 100 and the other end communicating with the gate valve 30. The one end of the substrate entrance 180 is opened and closed by a cover 156.

The cover 156 vertically extends from an edge of the ring plate 150. The cover 156 is interlocked with the ascending/descending operations of the substrate susceptor 140 to open or close the passage 182 of the substrate entrance 180. That is, the cover 156 opens or closes the passage 182 to allow the passage 182 of the substrate entrance 180 to be partitioned as an independent space with respect to the inner space of the process chamber 100.

The etching process in the substrate treating apparatus including the above-described constitutions will be described as follows.

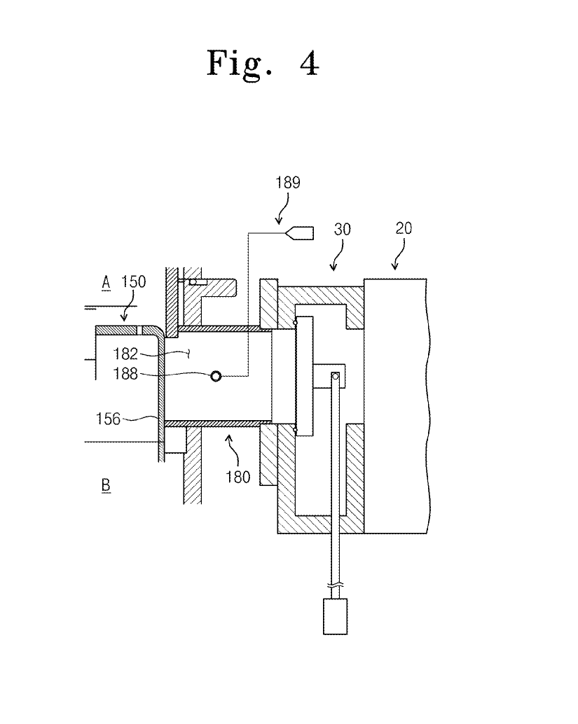

As shown in FIG. 2, the substrate S is loaded into the process chamber 100 through the passage 182 of the substrate entrance 180 and then is placed on the substrate susceptor 140 in the state where the substrate susceptor 140 descends by the descending operation thereof. When the loading of the substrate is completed, as shown in FIGS. 1 and 4, the substrate susceptor 140 ascends by the ascending operation thereof. Here, the passage 182 of the substrate entrance 180 is closed by the cover 156. That is, the passage 182 of the substrate entrance 180 is provided as an independent space with respect to the inner space of the process chamber 100 by the cover 156 and is filled with the inert gas (for example, a nitrogen gas). Also, the reactive gas is supplied into the process region A to react with the substrate in the state where the process region A is surrounded by the gas injection unit 130, the upper dome 120, the substrate susceptor 140, and the ring plate 150. Here, the reactive gas in the process region A does not contact other metals except for the quartz material while the etching process is performed. Thus, it may prevent the chamber and the substrate from being contaminated due to the reaction between the reactive gas and the metals. In addition, the inert gas may be continuously supplied into the passage 182 of the substrate entrance 180 while the etching process is performed.

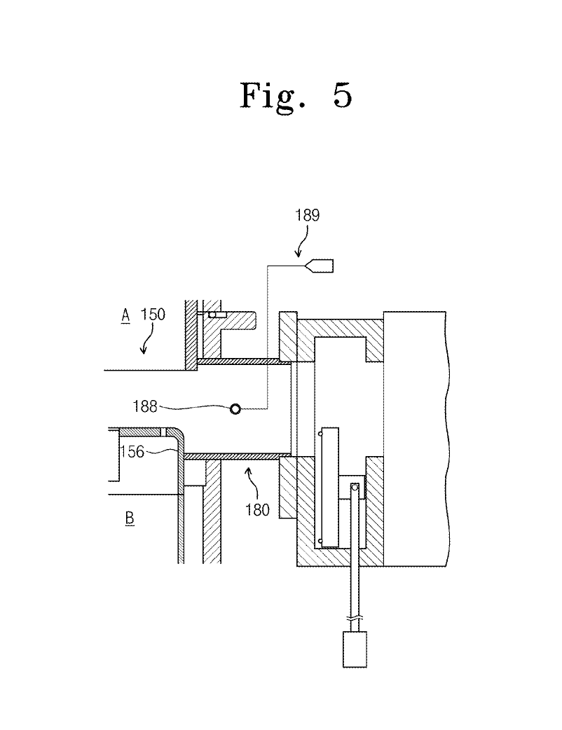

Referring to FIGS. 2 and 5, when the etching process is completed, the gate valve 30 is opened, and the substrate susceptor 140 descends by the descending operation thereof to unload the substrate. Here, since the inert gas captured in the passage 182 of the substrate is exhausted into the process chamber 100, it may prevent the etching gas remaining in the inner space of the process chamber 100 from being mixed into the loadlock chamber 20 through the substrate entrance 180.

In particular, the inside of the loadlock chamber 20 is maintained at a pressure that is greater than that of the inside of the process chamber 100 to prevent the residual etching gas from being mixed when the substrate is loaded into or unloaded from the process chamber 100.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description. Therefore, the preferred embodiments should be considered in descriptive sense only and not for purposes of limitation.

1. A gas phase etching apparatus comprising:
a process chamber having an inner space that is defined by a chamber body having an opened upper portion and an upper dome having an opened lower portion and detachably coupled to an upper portion of the chamber body;
a substrate susceptor disposed in the inner space to ascend and descend by a driving unit; and
a ring plate disposed on the substrate susceptor to cover a space between the substrate susceptor and an outer wall of the process chamber so that the inner space is partitioned into a process region defined above the substrate susceptor and an exhaust region defined below the substrate susceptor,
wherein the process region partitioned by the ring plate is surrounded by the upper dome, and the exhaust region is surrounded by the chamber body.

2. The gas phase etching apparatus of claim 1, further comprising a gas injection unit disposed on the upper dome to face the substrate susceptor, the gas injection unit receiving a reactive gas from a gas supply device to supply the reactive gas to the process region.

3. The gas phase etching apparatus of claim 2, wherein the gas injection unit comprises:
a circular gas introduction plate formed of a quartz material, the circular gas introduction plate being connected to a gas supply tube at an upper central portion thereof to diffuse the reactive gas downward; and
a shower plate formed of the quarts material and coupled to a lower portion of the circular gas introduction plate, wherein a plurality of injection holes vertically pass through the shower plate to inject the reactive gas supplied through the circular gas introduction plate downward.

4. The gas phase etching apparatus of claim 1, wherein the ring plate comprises a plurality of exhaust holes.

5. The gas phase etching apparatus of claim 1, wherein the upper dome is formed of the quartz material.

6. The gas phase etching apparatus of claim 1, wherein each of the upper dome, the substrate susceptor, and the ring plate which surround the process region is formed of the quartz material.

7. The gas phase etching apparatus of claim 1, wherein the process chamber further comprises a substrate entrance disposed in one side of the chamber body to provide a passage for loading/unloading the substrate into/from the inner space of the process chamber, and
the ring plate further comprises a cover vertically extending from an edge thereof and interlocked with the ascending/descending operations of the substrate susceptor to open or close the passage of the substrate entrance to allow the passage of the substrate entrance to be partitioned as an independent space with respect to the inner space of the process chamber.

8. The gas phase etching apparatus of claim 7, further comprising a purge supply unit for supplying an inert gas into the passage of the substrate entrance,
wherein the substrate entrance comprises a gas supply hole through which the inert gas supplied through the purge supply unit is supplied into the passage.

9. The gas phase etching apparatus of claim 1, wherein the chamber body is formed of a hastelloy material and has a surface treated through electrolytic polishing or complex electrolytic polishing.

10. The gas phase etching apparatus of claim 3, wherein the ring plate comprises a plurality of exhaust holes.

11. The gas phase etching apparatus of claim 3, wherein the upper dome is formed of the quartz material.

12. The gas phase etching apparatus of claim 3, wherein each of the upper dome, the substrate susceptor, and the ring plate which surround the process region is formed of the quartz material.

13. The gas phase etching apparatus of claim 3, wherein the process chamber further comprises a substrate entrance disposed in one side of the chamber body to provide a passage for loading/unloading the substrate into/from the inner space of the process chamber, and
the ring plate further comprises a cover vertically extending from an edge thereof and interlocked with the ascending/descending operations of the substrate susceptor to open or close the passage of the substrate entrance to allow the passage of the substrate entrance to be partitioned as an independent space with respect to the inner space of the process chamber.
